(19) United States
(12) Patent Application Publication
(10) Pub. No.: US 2024/0244779 A1
(43) Pub. Date: Jul. 18, 2024

(54) SOLID STATE DRIVE ENCLOSURE

(71) Applicant: Micron Technology, Inc., Boise, ID (US)

(72) Inventors: Suresh Reddy Yarragunta, Bangalore (IN); Deepu Narasimiah Subhash, Bangalore (IN)

(21) Appl. No.: 18/509,939

(22) Filed: Nov. 15, 2023

Related U.S. Application Data
(60) Provisional application No. 63/439,632, filed on Jan. 18, 2023.

(51) Int. Cl. H05K 5/02; H05K 7/20

(52) U.S. Cl. CPC H05K 5/026; H05K 7/20336; H05K 7/2039

(57) ABSTRACT

A number of embodiments of the present disclosure include an solid state drive (SSD) enclosure comprising a first component, wherein the first component is configured to cover a first side of an SSD, a second component; and a third component, wherein the third component is configured receive the second component, wherein the third component is configured to be releasably coupled to the second component, and wherein the second component and the third component are configured to cover a second side of the SSD.

### PRIORITY INFORMATION

This application claims the benefit of U.S. Provisional Application No. 63/439,632, filed on Jan. 18, 2023, the contents of which are incorporated herein by reference.

### TECHNICAL FIELD

Embodiments of the disclosure relate generally to solid state drive (SSDs), more specifically to an SSD enclosure.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 illustrates an example computing system that includes a memory sub-system in accordance with some embodiments of the present disclosure.

FIG. 2. illustrates a first portion of an SSD enclosure.

FIG. 3 illustrates a second portion of an SSD enclosure.

FIGS. 4A-4C illustrate a number of third portions of an SSD enclosure.

FIGS. 5A-5C illustrate SSD enclosures including a first portion, a second portion, and a third portion.

### DETAILED DESCRIPTION

A number of embodiments of the present disclosure include a solid state drive (SSD) enclosure, comprising a first component, wherein the first component is configured to cover a first side of an SSD, a second component; and a third component, wherein the third component is configured receive the second component, wherein the third component is configured to be releasably coupled to the second component, and wherein the second component and the third component are configured to cover a second side of the SSD.

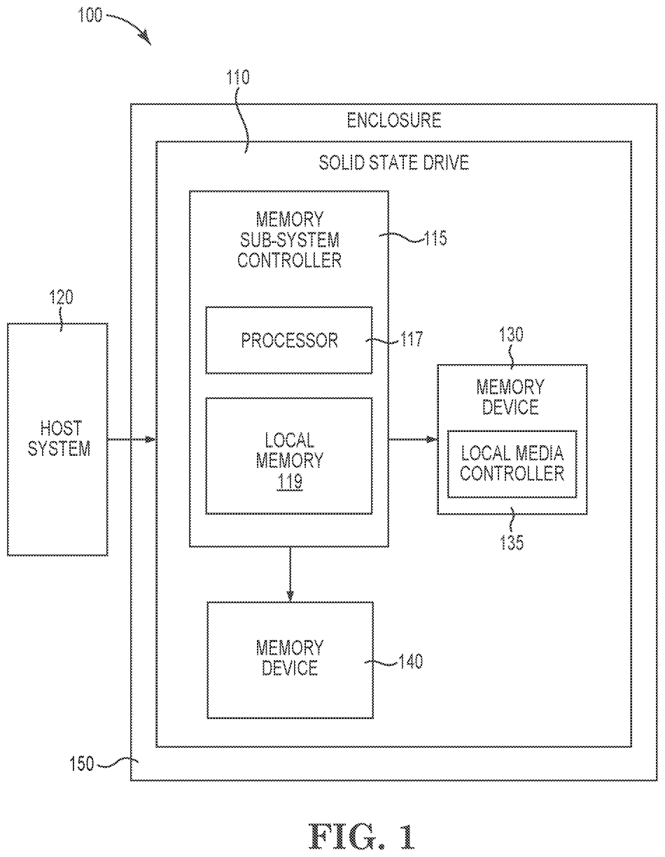

Aspects of the present disclosure are directed to a memory system enclosure, in particular to an SSD enclosure that can include a portion that can be selected and sized such that the SSD enclosure can meet a number of SSD enclosure form factors. The memory system can be or can include a memory sub-system, which can be a storage system, storage device, a memory module, or a combination of such. An example of a memory sub-system is a storage system such as a solid-state drive (SSD). Examples of storage devices and memory modules are described below in conjunction with FIG. 1, et alibi. In general, a host system can utilize a memory sub-system that includes one or more components, such as memory devices that store data. The host system can provide data to be stored at the memory sub-system and can request data to be retrieved from the memory sub-system.

An SSD enclosure according to embodiments of the present disclosure can include a first portion, a second portion, and a third portion. An SSD enclosure can protect the SSD (e.g., the components of the SSD) from the outside environment and also provide heat transfer functionality to remove heat from the SSD to cool the SSD. An SSD enclosure can include a first portion (e.g., a back of the SSD enclosure) and a second portion (e.g., a front of the SSD enclosure). The first and second portion of the SSD enclosure can be sized to hold SSDs of varying size, such as any Enterprise and Data Center Standard Form Factor (EDSFF) SSD. The first and second portions of the SSD can be metal and/or plastic and can be formed by die casting. The third portion of the SSD can be configured to be removably coupled to and received by the second portion of the SSD enclosure. The third portion of the SSD enclosure can include a heat transfer portion, such as a heat spreader, and be sized and selected to provide suitable heat transfer capabilities for an SSD housed in the SSD enclosure. The first and second portions of the SSD can be used with a number of sizes of the third portion such that the SSD enclosure can be used with various SSD form factors. For example, the third portion can be sized and selected such that the SSD enclosure is an EDSFF E1.S 9.5 mm enclosure, an EDSFF E1.S 15 mm enclosure, or an EDSFF E1.S 25 mm enclosure. FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD). Examples of memory modules include a dual in-line memory module (DIMM), a small outline DIMM (SO-DIMM), and various types of non-volatile dual in-line memory modules (NVDIMMs). Enclosure 150 can be configured to cover the components of the memory sub-system 110, such that enclosure 150 protects the components of the memory sub-system 110 from the outside environment and can provide heat transfer functionality to remove heat from the memory sub-system 110. Enclosure 150 can include a first portion that is coupled to a second portion; and a third portion that is coupled to the second portion. The third portion of enclosure 150 can be configured to be removably coupled to and received by the second portion of the enclosure 150. The first and second portions of the enclosure 150 can be used with a number of sizes of the third portion such that the enclosure 150 can be used with several SSD form factors. For example, the third portion can be sized and selected such that the enclosure 150 is an EDSFF E1.S 9.5 mm enclosure, an EDSFF E1.S 15 mm enclosure, or an EDSFF E1.S 25 mm enclosure.

The computing system 100 can be a computing device such as a desktop computer, laptop computer, server, network server, mobile device, a vehicle (e.g., airplane, drone, train, automobile, or other conveyance), Internet of Things (IOT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., an SSD controller), and a storage protocol controller (e.g., PCIe controller, SATA controller). The host system 120 uses the memory sub-system controller 115, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), Small Computer System Interface (SCSI), a double data rate (DDR) memory bus, a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), or any other interface. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the PCIe interface. The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via the same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random-access memory (DRAM) and synchronous dynamic random-access memory (SDRAM).

Some examples of non-volatile memory devices (e.g., memory device 130) include negative-and (NAND) type flash memory and write-in-place memory, such as three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130, 140 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLC) can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as three-dimensional cross-point arrays of non-volatile memory cells and NAND type memory (e.g., 2D NAND, 3D NAND) are described, the memory device 130 can be based on any other type of non-volatile memory or storage device, such as such as, read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

The memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or another suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address, physical media locations, etc.) that are associated with the memory devices 130. The memory sub-system controller 115 can further include host interface circuitry to communicate with the host system 120 via the physical host interface. The host interface circuitry can convert the commands received from the host system into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory device 130 and/or the memory device 140.

In some embodiments, the memory device 130 includes local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local controller 135) for media management within the same memory device package. An example of a managed memory device is a managed NAND (MNAND) device.

In some embodiments, the memory sub-system controller 115 can include a processor 117 (processing device) configured to execute instructions stored in local memory 119 for performing the operations described herein.

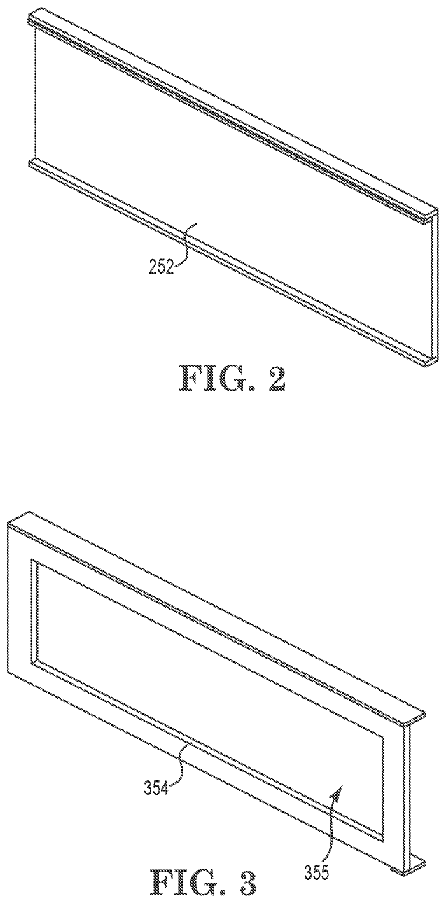

FIG. 2 illustrates a first portion of an SSD enclosure. The first portion 252 of the SSD enclosure can be the back of the SSD enclosure. The first portion 252 of the SSD enclosure can be formed of metal and/or plastic and can be formed via die casting. In a number of embodiments, the first portion 252 of the SSD enclosure can be part of an E1.S 9.5 mm enclosure, an E1.S 15 mm enclosure, and/or an E1.S 25 mm enclosure. The first portion 252 of the SSD enclosure can be a heat spreader to remove heat from the SSD enclosed by the first portion 252 of the SSD enclosure.

FIG. 3 illustrates a first portion of an SSD enclosure. The second portion 354 of the SSD enclosure can be the front of the SSD enclosure. The second portion 354 of the SSD enclosure can be formed of metal and/or plastic and can be formed via die casting. The second portion 354 of the SSD enclosure. In a number of embodiments, the second portion 354 of the SSD enclosure can be part of an E1.S 9.5 mm enclosure, an E1.S 15 mm enclosure, and/or an E1.S 25 mm enclosure. The second portion 354 of the SSD enclosure can be couplable to a first portion of the SSD enclosure. The second portion 354 of the SSD enclosure can include an opening 355 to receive a third portion of the SSD enclosure.

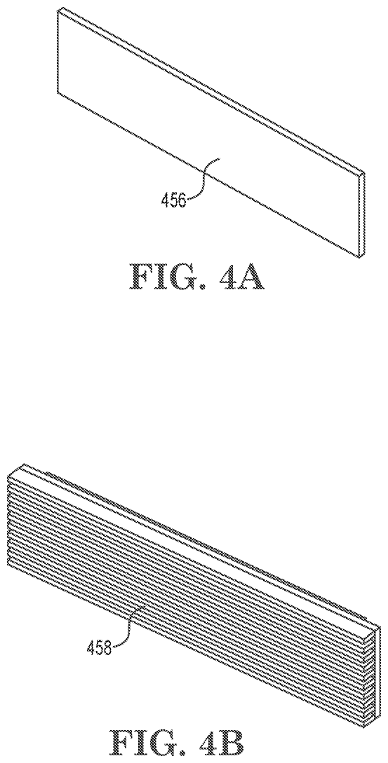

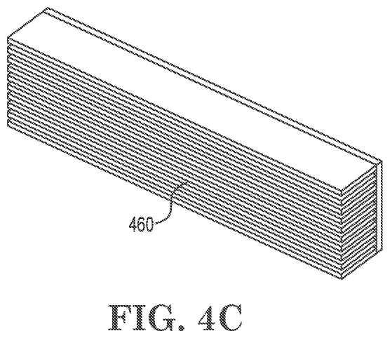

FIGS. 4A-4C illustrate a number of third portions of an SSD enclosure. In FIG. 4A, third portion 456 of an SSD enclosure can be a top heat spreader and/or heat sink for an SSD enclosure. Portion 456 can be sized and selected to provide heat transfer functionality for an SSD in an E1.S 9.5 mm enclosure. Portion 456 can be couplable to a second portion (e.g., second portion 354 in FIG. 3) of an SSD enclosure. Portion 456 can be formed from metal and can be formed via extrusion. Portion 456 can include a heat pipe and/or a vapor chamber to provide heat transfer and/or cooling functionality for the enclosure.

In FIG. 4B, third portion 458 of an SSD enclosure can be a top heat spreader and/or heat sink for an SSD enclosure. Portion 458 can be sized and selected to provide heat transfer functionality for an SSD in an E1.S 15 mm enclosure. Portion 458 can be couplable to a second portion (e.g., second portion 354 in FIG. 3) of an SSD enclosure. Portion 458 can be formed from metal and can be formed via extrusion. Portion 458 can include a heat pipe and/or a vapor chamber to provide heat transfer and/or cooling functionality for the enclosure.

In FIG. 4C, portion 460 of an SSD enclosure can be a top heat spreader and/or heat sink for an SSD enclosure. Portion 460 can be sized and selected to provide heat transfer functionality for an SSD in an E1.S 25 mm enclosure. Portion 460 can be couplable to a second portion (e.g., second portion 354 in FIG. 3) of an SSD enclosure. Portion 460 can be formed from metal and can be formed via extrusion. Portion 460 can include a heat pipe and/or a vapor chamber to provide heat transfer and/or cooling functionality for the enclosure.

Portion 456, 458, and 460 in FIGS. 4A, 4B, and 4C, respectively, are versions of a top heat spreader or heat sink that can be coupled to a bottom heat spreader within an enclosure configured to receive heat. In some embodiments, portion 456 can be a top heat spreader component for E1.S 9.5 mm enclosure, portion 458 can be a top heat spreader component for E1.S 15 mm enclosure, and portion 460 can be a top heat spreader component for E1.S 25 mm enclosure.

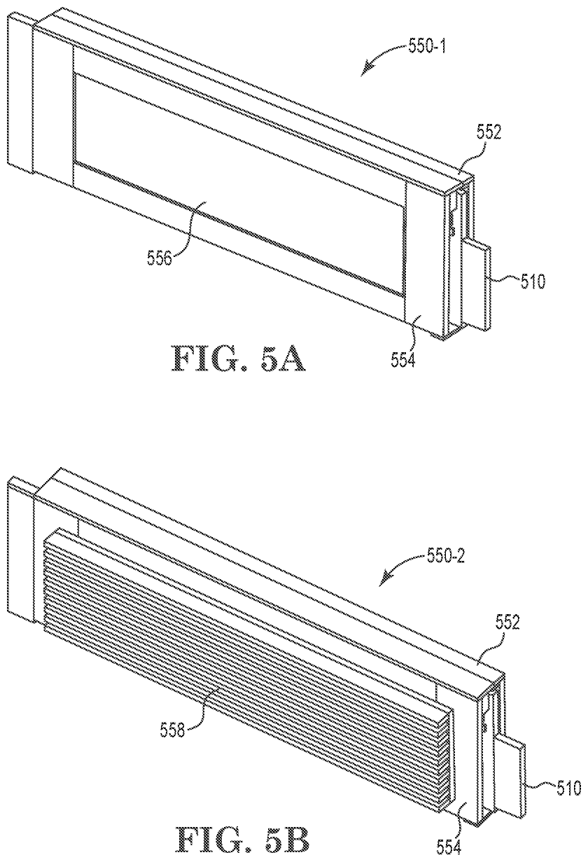

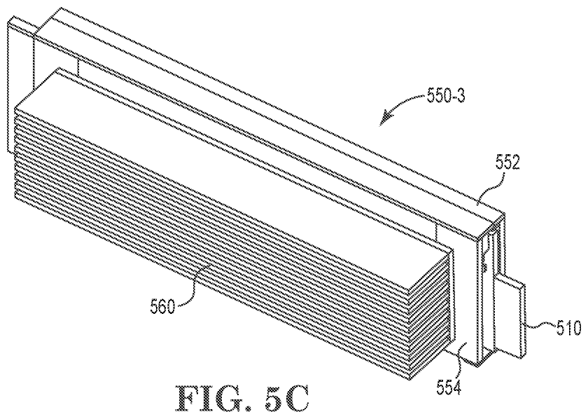

FIGS. 5A-5C illustrate SSD enclosures including a first portion, a second portion, and a third portion. In FIG. 5A, SSD enclosure 550-1 includes a first portion 552 coupled to a second portion 554 and a third portion 556 coupled to the second portion 554. The first portion 552, second portion 554, and third portion 556 of enclosure 550-1 are configured to enclose SSD 510. The third portion 556 of enclosure 550-1 can be selected such that enclosure 550-1 is an EDSFF E1.S 9.5 mm enclosure.

In FIG. 5B, SSD enclosure 550-2 includes a first portion 552 coupled to a second portion 554 and a third portion 558 coupled to the second portion 554. The first portion 552, second portion 554, and third portion 558 of enclosure 550-2 are configured to enclose SSD 510. The third portion 558 of enclosure 550-2 can be selected such that enclosure 550-2 is an EDSFF E1.S 15 mm enclosure.

In FIG. 5C, SSD enclosure 550-3 includes a first portion 552 coupled to a second portion 554 and a third portion 560 coupled to the second portion 554. The first portion 552, second portion 554, and third portion 560 of enclosure 550-3 are configured to enclose SSD 510. The third portion 560 of enclosure 550-3 can be selected such that enclosure 550-3 is an EDSFF E1.S 25 mm enclosure.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

1. A solid state drive (SSD) enclosure, comprising:
a first portion, wherein the first portion is configured to cover a first side of an SSD;
a second portion; and
a third portion, wherein the third portion is configured receive the second portion, wherein the third portion is configured to be releasably coupled to the second portion, and wherein the second portion and the third portion are configured to cover a second side of the SSD.

2. The enclosure of claim 1, wherein the first portion is a first heat spreader.

3. The enclosure of claim 1, wherein the second portion is a second heat spreader.

4. The enclosure of claim 1, wherein the second portion is configured to include a closed vapor chamber cooling portion.

5. The enclosure of claim 1, wherein the second portion is configured to include a heat pipe portion.

6. The enclosure of claim 1, wherein the enclosure is an Enterprise and Data Center Standard Form Factor (EDSFF) enclosure.

7. The enclosure of claim 6, wherein the EDSFF enclosure is a E1.S form factor enclosure.

8. A system, comprising:
a solid state drive (SSD) enclosure including:
a first portion, wherein the first portion is configured to cover a first side of an SSD;
a number of second portions; and
a third portion, wherein the third portion is configured receive one of the number of second portions and wherein the second portion and the third portion are configured to cover a second side of the SSD.

9. The system of claim 8, wherein each of the number of second portions are configured to provide particular cooling characteristics for the SSD.

10. The system of claim 8, wherein one the number of second portions is selected such that the enclosure is an E1.S 9.5 mm enclosure.

11. The system of claim 8, wherein one the number of second portions is selected such that the enclosure is an E1.S 15 mm enclosure.

12. The system of claim 8, wherein one the number of second portions is selected such that the enclosure is an E1.S 25 mm enclosure.

13. The system of claim 8, wherein the first and third portion are coupled to each other.

14. The system of claim 8, wherein the number of second portions include a heat pipe portion.

15. A solid state drive (SSD) enclosure, comprising:
a first portion, wherein the first portion is configured as a first heat spreader to cool a solid state drive (SSD);
a second portion, wherein the second portion is configured as a second heat spreader to cool the SSD; and
a third portion, wherein the third portion is configured to be releasably coupled to the second portion.

16. The enclosure of claim 15, wherein the first portion and the third portion are cast.

17. The enclosure of claim 15, wherein the second portion is extruded.

18. The enclosure of claim 15, wherein the first and third portion are coupled to each other.

19. The enclosure of claim 15, wherein the second portion is selected to meet cooling requirements for the SSD.

20. The enclosure of claim 15, wherein the second portion is selected based on the form factor of the SSD.
